(19) United States
(12) Patent Application Publication
(10) Pub. No.: US 2025/0250194 A1
(43) Pub. Date: Aug. 7, 2025

(54) METHOD FOR MANUFACTURING FINE SURFACE ROUGHNESS ON QUARTZ GLASS SUBSTRATE

(71) Applicant: NALUX CO., LTD., Osaka (JP)

(72) Inventors: Kenji TANIBE, Osaka (JP); Kazuya YAMAMOTO, Osaka (JP)

(73) Assignee: NALUX CO., LTD., Osaka (JP)

(21) Appl. No.: 19/188,387

(22) Filed: Apr. 24, 2025

Related U.S. Application Data
(63) Continuation-in-part of application No. 17/838,654, filed on Jun. 13, 2022.
Application No. 17/838,654 is a continuation-in-part of application No. PCT/JP2020/029010, filed on Jul. 22, 2020.
(60) Provisional application No. 62/954,803, filed on Dec. 30, 2019.

(51) Int. Cl. C03C 15/00; G03F 7/00; H01J 37/32

(52) U.S. Cl. CPC C03C 15/00; G03F 7/0002; H01J 37/32449; H01J 2237/3341

(57) ABSTRACT

A method for manufacturing fine surface roughness on a surface of a quartz glass substrate, the method comprising: making the substrate undergo ion etching with argon gas alone such that through the ion etching a layer of a thickness of 20 nanometers or greater is removed from the surface; and making the substrate undergo reactive ion etching with trifluoromethane gas or a mixed gas of trifluoromethane and oxygen such that after the reactive ion etching surface roughness having an average pitch in a range from 30 nanometers to 200 nanometers is formed and there exists light having a wavelength in a range from 350 to 800 nanometers, for the light normal-incidence reflectivity of the surface being 1.5 percent or smaller or there exists light having a wavelength in a range from 200 to 350 nanometers, for the light normal-incidence reflectivity of the surface being 2.5 percent or smaller.

### CROSS REFERENCE TO RELATED APPLICATION

This is a Continuation-in-Part of U.S. patent application Ser. No. 17/838,654 filed Jun. 13, 2022, which in turn is a Continuation-in-Part of International Patent Application No. PCT/JP2020/029010, filed Jul. 29, 2020, and which claims priority from U.S. Provisional Patent Application No. 62/954,803, filed Dec. 30, 2019. The contents of these applications are hereby incorporated by reference.

### TECHNICAL FIELD

The present invention relates to a method for manufacturing fine surface roughness on a quartz glass substrate.

### BACKGROUND ART

An antireflective structure that includes fine surface roughness formed on a surface of a quartz glass substrate, the fine surface roughness having a pitch (period) equal to or smaller than wavelength of light, is used for optical elements. As methods for manufacturing such fine surface roughness, a method including the steps of forming a pattern mask on a surface by electron beam lithography and of etching the surface to form fine surface roughness thereon (Patent document 1), a method including the steps of forming a pattern mask on a surface by spattering and of etching the surface to form fine surface roughness thereon (Patent document 2) and a method including the step of distributing nanoparticles over a surface to form fine surface roughness thereon (Patent document 3) are known.

The conventional methods described above, however, have disadvantages described below. The method using electron beam lithography requires too much processing time and therefore can hardly be used to form fine surface roughness over a sufficiently large surface area. In the method using spattering, a mask used to form a desired shape of fine surface roughness can hardly be obtained by adjusting the conditions, and therefore high antireflective performance cannot be obtained. The method using nanoparticles requires a number of processing steps in order to form an intermediate layer between a quartz glass substrate and nanoparticles and also higher costs because of expensive nanoparticles.

Further, a method for manufacturing fine surface roughness on a glass substrate through reactive ion etching has been developed (Patent document 4). The method uses, as an etching mask, polymer particles that have been generated by chemical reactions between glass and etching gas and distributed at random on a glass substrate. In the method, however, the shape of fine surface roughness is susceptible to types of glass and to surface conditions of the glass, because the method uses chemical reactions to generate the etching mask, and therefore fine surface roughness having a desired shape can hardly be manufactured with stability.

Thus, a method for manufacturing fine surface roughness having a desired shape over a large area of a quartz glass substrate with stability, the method using a relatively simple manufacturing process has not been developed.

Accordingly, there is a need for a method for manufacturing fine surface roughness having a desired shape over a large area of a quartz glass substrate with stability, the method using a relatively simple manufacturing process.

### PRIOR ART DOCUMENTS

### Patent Documents

Patent document 1: JP2001272505A
Patent document 2: JP2019008082A
Patent document 3: JP2006259711A
Patent document 4: U.S. Pat. No. 8,187,481B1

The object of the present invention is to provide a method for manufacturing fine surface roughness having a desired shape over a large area of a quartz glass substrate with stability, the method using a relatively simple manufacturing process.

### SUMMARY

A method for manufacturing fine surface roughness on a surface of a quartz glass substrate, the method comprising: making the quartz glass substrate undergo ion etching with argon gas alone such that through the ion etching with argon a layer of a thickness of 20 nanometers or greater is removed from a surface of the quartz glass substrate; and making the quartz glass substrate undergo reactive ion etching with trifluoromethane (CHF₃) gas or a mixed gas of trifluoromethane (CHF₃) and oxygen such that after the reactive ion etching surface roughness having an average pitch in a range from 30 nanometers to 200 nanometers is formed on the surface of the quartz glass substrate and there exists light having a wavelength in a range from 350 to 800 nanometers, for the light normal-incidence reflectivity of the surface being 1.5 percent or smaller or there exists light having a wavelength in a range from 200 to 350 nanometers, for the light normal-incidence reflectivity of the surface being 2.5 percent or smaller.

### BRIEF DESCRIPTION OF DRAWINGS

FIG. 1 shows constituent elements of an etching apparatus used for a method for manufacturing fine surface roughness on a quartz glass substrate according to an embodiment of the present invention;

FIG. 2 is a flowchart for describing a method for manufacturing fine surface roughness on a quartz glass substrate according to an embodiment of the present invention;

FIG. 3 is a drawing for illustrating the method for manufacturing fine surface roughness on a quartz glass substrate according to the embodiment of the present invention shown in FIG. 2;

FIG. 4 is a flowchart for describing a method for manufacturing fine surface roughness on a quartz glass substrate according to another embodiment of the present invention;

FIG. 5 is a drawing for illustrating the method for manufacturing fine surface roughness on a quartz glass substrate according to the embodiment of the present invention shown in FIG. 4;

FIG. 6 illustrates how the third etching process changes the shape of fine surface roughness formed on the surface of the quartz glass substrate;

FIG. 7 shows transmittance of quartz glass substrates with and without fine surface roughness;

FIG. 8 shows reflectance of the quartz glass substrate with and without fine surface roughness;

FIG. 9 is a photo showing reflection of a quartz glass substrate on which fine surface roughness is formed after the first etching process and the second etching process and reflection of a quartz glass substrate on which no fine surface roughness is formed;

FIG. 10 is a photo of a waterdrop on a surface of a quartz glass substrate on which no fine surface roughness is formed;

FIG. 11 is a photo of a waterdrop on a surface of a quartz glass substrate with fine surface roughness which has undergone etching using trifluoromethane (CHF₃) gas in the third etching process;

FIG. 12 is a photo of a waterdrop on a surface of a quartz glass substrate with fine surface roughness which has undergone etching using oxygen gas in the third etching process;

FIG. 13 is a flowchart for describing a method for manufacturing fine surface roughness on a quartz glass substrate according to still another embodiment of the present invention;

FIG. 14 is a drawing for illustrating the method for manufacturing fine surface roughness on a quartz glass substrate according to the embodiment of the present invention;

FIG. 15 illustrates how the shape of the fine surface roughness formed on the surface of the quartz glass substrate changes through the wet coating process;

FIG. 16 shows transmittance of a quartz glass substrate provided with fine surface roughness that has been made to undergo a wet coating process;

FIG. 17 shows reflectance of the quartz glass substrate provided with fine surface roughness that has been made to undergo the wet coating process;

FIG. 18 shows reflectance of a quartz glass substrate on which no fine surface roughness is formed and which has been made to undergo the wet coating process;

FIG. 19 is a photo of a waterdrop on a surface of a quartz glass substrate on which no fine surface roughness is formed:

FIG. 20 is a photo of a waterdrop on a surface of a quartz glass substrate on which fine surface roughness is formed, the fine surface roughness having not been made to undergo wet coating;

FIG. 21 is a photo of a waterdrop on a surface of a quartz glass substrate on which fine surface roughness is formed, the fine surface roughness having been made to undergo wet coating;

FIG. 22 shows transmittance of a quartz glass substrate on which fine surface roughness is formed;

FIG. 23 is a flowchart for outlining the methods for manufacturing fine surface roughness on a quartz glass substrate according to the present invention;

FIG. 24 shows a SEM (scanning electron microscope) image of a surface of the “with argon” substrate;

FIG. 25 shows a SEM (scanning electron microscope) image of a surface of the “without argon” substrate;

FIG. 26 shows transmittance of quartz glass substrates with and without fine surface roughness; and

FIG. 27 shows transmittance of quartz glass substrates with and without fine surface roughness.

### DESCRIPTION OF EMBODIMENTS

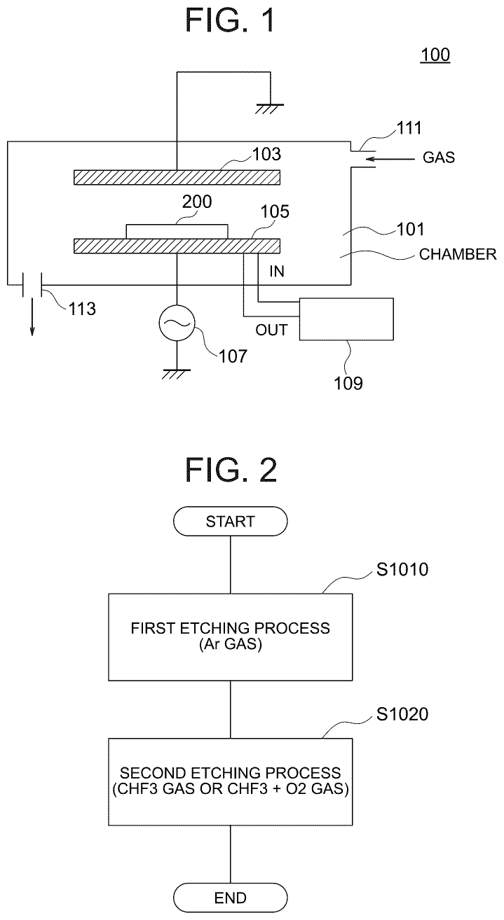

FIG. 1 shows components of an etching apparatus 100 used for a method for manufacturing fine surface roughness on a quartz glass substrate according to an embodiment of the present invention. The etching apparatus 100 has a reaction chamber 101. After having been evacuated, the reaction chamber 101 is supplied with a gas through a gas supply port 111. The flow rate of gas to be supplied can be adjusted. The reaction chamber 101 is further provided with a gas exhaust port 113, on which a valve not illustrated in the drawing is installed. By manipulating the valve, gas pressure in the reaction chamber 101 can be kept at a desired value. The reaction chamber 101 is provided with an upper electrode 103, which is usually grounded, and a lower electrode 105, which is usually connected to a high-frequency power source 107. By applying a high-frequency voltage across both the electrodes using the high-frequency power source 107, plasma can be generated from the gas in the reaction chamber 101. On the lower electrode 105, a target to be processed is placed. The lower electrode 105 can be cooled to a desired temperature by a cooling device 109. The cooling device 109 is a water-cooling type chiller, for example. The reason why the lower electrode 105 is cooled is that etching reaction can be controlled by keeping a substrate 200 (the target) at a desired temperature.

FIG. 2 is a flowchart for describing a method for manufacturing fine surface roughness on a quartz glass substrate according to an embodiment of the present invention.

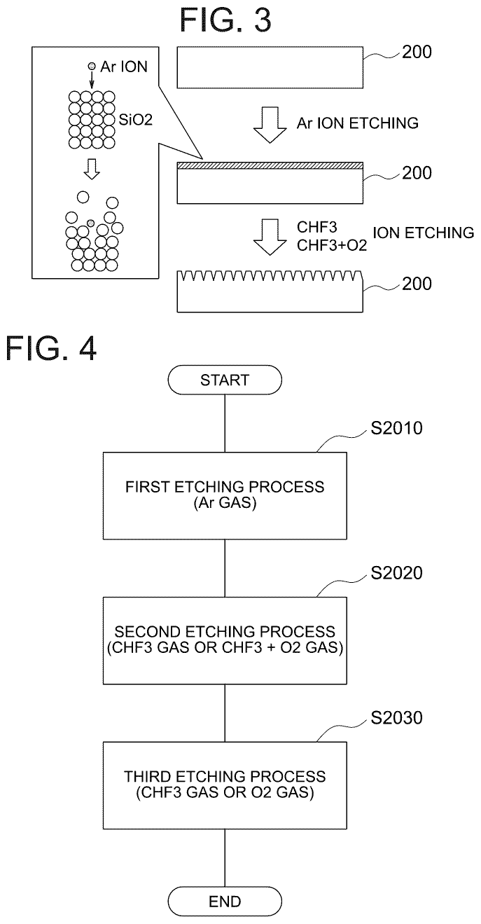

FIG. 3 is a drawing for illustrating the method for manufacturing fine surface roughness on a quartz glass substrate according to the embodiment of the present invention shown in FIG. 2.

In step S1010 of FIG. 2, a quartz glass substrate 200 is placed on the lower electrode 105, the etching apparatus 100 is supplied with argon gas, and a high-frequency voltage is applied to the lower electrode 105 by the high-frequency power source 107. The state of argon gas changes into plasma by the high-frequency voltage, and argon ions are generated. The argon cations are attracted to the lower electrode 105 that is charged negative with electrons and collide against a surface of the quartz glass substrate 200 so that a physical etching process takes place on the surface. The etching process in the present step is referred to as a first etching process.

Table 1 shows an example of conditions of the first etching.

TABLE 1

| | Gas | | | | |
|---|---|---|---|---|---|
| | component | | RF (high- | | |
| Gas | and gas | | frequency) | | Etching |
| pressure | flow rate | Mode | power | Temperature | time |
| 1.0 Pa | Ar: 20 ml/min | Ion | 100 W | 2.0° C. | 1800 sec |
| | | etching | | | |

Concerning conditions shown in Table 1 and tables given below, the frequency of the high-frequency power source 107 is 13.56 MHz and values of temperature shown there are those of the lower electrode 105, which are controlled by the cooling device 109.

Concerning conditions shown in Table 1 and tables given below, “ion etching” means etching that is carried out mainly physically through collision of ions against the target, and “radical etching” means chemical etching that is carried out through chemical reactions between radicals and a surface of the target.

As shown in FIG. 3, the arrangement of atoms on the surface of the quartz glass substrate 200 is changed by the first etching process in such a way that fine surface roughness can be easily formed on the surface of the quartz glass substrate 200 in a second etching process described later independently of an initial state of the surface.

In step S1020 of FIG. 2, the etching apparatus 100 is supplied with trifluoromethane (CHF₃) gas or a mixed gas of trifluoromethane (CHF₃) and oxygen, and a high-frequency voltage is applied to the lower electrode 105 by the high-frequency power source 107. The state of trifluoromethane (CHF₃) gas or of the oxygen gas changes into plasma by the high-frequency voltage, and trifluoromethane (CHF₃) cations or oxygen cations are generated. The trifluoromethane (CHF₃) cations or oxygen cations are attracted to the lower electrode 105 that is charged negative with electrons and collide against the surface of the quartz glass substrate 200 so that a physical etching process takes place on the surface. Further, trifluoromethane (CHF₃) ions or radicals react with silicon dioxide (SiO₂) that constitute the quartz glass to form various reaction products such as silicon fluoride (SiF₄) and oxygen (O₂). When the reaction products leave the surface of the quartz glass substrate 200, an additional etching process takes place. The oxygen gas removes polymer particles that have been generated by the trifluoromethane (CHF₃) gas and have adhered onto the surface of the quartz glass substrate 200 so that antireflection performance is improved. The ratio of oxygen gas flow rate to the total gas flow rate is preferably in a range from 0 to 50 percent. The etching process in the present step is referred to as a second etching process.

As shown in FIG. 3, fine surface roughness is formed on the quartz glass substrate 200 by the second etching process.

Table 2 shows an example of conditions of the second etching.

TABLE 2

| | Gas | | | | |
|---|---|---|---|---|---|
| | component | | RF (high- | | |
| Gas | and gas | | frequency) | | Etching |
| pressure | flow rate | Mode | power | Temperature | time |
| 1.7 Pa | O2: 2 ml/min | Ion | 175 W | 2.0° C. | 1800 sec |
| | CHF3: 18 | etching | | | |
| | ml/min | | | | |

Concerning the fine surface roughness formed on the quartz glass substrate after the second etching, an average pitch (period) is 120 nanometers, and an average depth is 280 nanometers.

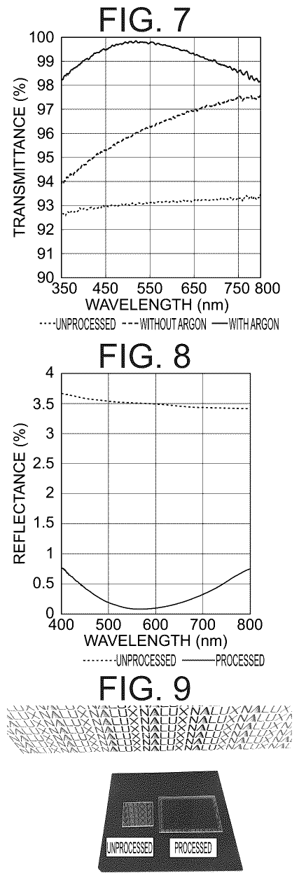

FIG. 7 shows transmittance of quartz glass substrates with and without fine surface roughness. The horizontal axis of FIG. 7 indicates wavelength, and the vertical axis of FIG. 7 indicates transmittance. The unit of the horizontal axis is nanometer, and the unit of the vertical axis is percent. In FIG. 7, the solid line marked with “with argon” represents transmittance of a quartz glass substrate with fine surface roughness formed on each of both sides of the substrate after the first etching process (an argon gas etching process) and the second etching process, the thick broken line marked with “without argon” represents transmittance of a quartz glass substrate with fine surface roughness formed on each of both sides of the substrate after the second etching process alone, and the thin broken line marked with “unprocessed” represents transmittance of a quartz glass substrate without fine surface roughness, the substrate having undergone neither the first etching nor the second etching. The conditions of the first etching described above are those shown in Table 1 and the conditions of the second etching described above are those shown in Table 2. According to FIG. 7, a value of transmittance at a certain wavelength of the “with argon” substrate is greater by 0.5 to 4 percent than a value of transmittance at the certain wavelength of the “without argon” substrate and greater by 5 to 7 percent than a value of transmittance at the certain wavelength of the “unprocessed” substrate across the whole range of wavelength.

Values of transmittance indicated by the vertical axis of FIG. 7 are measured values of normal-incidence transmissivity of each quartz glass substrate. Fine surface roughness is formed on each of both sides of the substrate under the same conditions. Since absorption of light by the substrate and scattering of light on a surface of the substrate are negligibly small, the following equations hold based on the Stokes relations.

Normal-incidence transmissivity of a substrate with fine surface roughness formed on each of both sides of the substrate (Tb)=1-2·(normal-incidence reflectivity of each surface with fine surface roughness (R))

$$R = ( 1 - Tb ) / 2$$

Normal-incidence transmissivity of each surface with fine surface roughness (T)=1-R

FIG. 8 shows reflectance of the quartz glass substrates with and without fine surface roughness. The horizontal axis of FIG. 8 indicates wavelength, and the vertical axis of FIG. 8 indicates reflectance. The unit of the horizontal axis is nanometer, and the unit of the vertical axis is percent. In FIG. 8, the solid line marked with “processed” represents reflectance of a quartz glass substrate with fine surface roughness formed after the first etching process (an argon gas etching process) and the second etching process and the broken line marked with “unprocessed” represents reflectance of the quartz glass substrate on which no fine surface roughness is formed, the substrate having undergone neither the first etching nor the second etching. According to FIG. 8, reflectance at a certain wavelength of the “processed” substrate is smaller by 2.5 to 3.5 percent than reflectance at the certain wavelength of the “unprocessed” substrate across the whole range of wavelength.

Values of reflectance indicated by the vertical axis of FIG. 8 are measured values of normal-incidence reflectivity of a quartz glass substrate. A measured value of normal-incidence reflectivity at a certain wavelength shown in FIG. 8 substantially agrees with a value estimated from a measured value of normal-incidence transmissivity at the certain wavelength of the quartz glass substrate shown in FIG. 7.

FIG. 9 is a photo showing reflection of a quartz glass substrate on which fine surface roughness is formed after the first etching process and the second etching process and reflection of a quartz glass substrate on which no fine surface roughness is formed. In FIG. 9, a portion of the quartz glass substrate on which fine surface roughness is formed is marked with “processed”, and a portion of the quartz glass substrate on which no fine surface roughness is formed is marked with “unprocessed”. While a reflected image of characters can be observed on the “unprocessed” substrate, that cannot be observed on the “processed” substrate. The observation verifies that reflectance of the “processed” substrate is smaller than that of the “unprocessed” substrate.

The inventors have made a finding that transmittance of a quartz glass substrate on which fine surface roughness is formed after the first etching process and the second etching process remarkably varies depending on conditions of the first etching process.

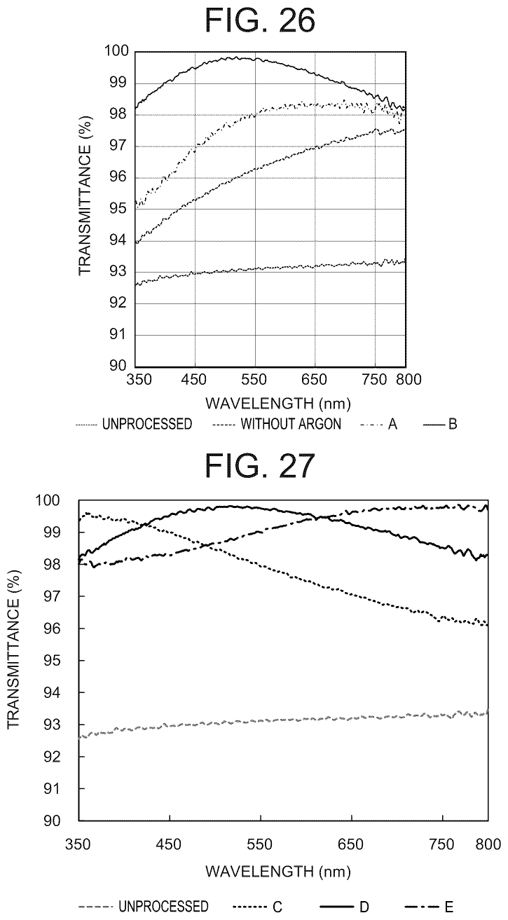

FIG. 26 shows transmittance of quartz glass substrates with and without fine surface roughness. The horizontal axis of FIG. 26 indicates wavelength, and the vertical axis of FIG. 26 indicates transmittance. The unit of the horizontal axis is nanometer, and the unit of the vertical axis is percent. In FIG. 26, the graph represented by the dotted line marked with “unprocessed” represents transmittance of a quartz glass substrate without fine surface roughness, the graph represented by the broken line marked with “without argon” represents transmittance of a quartz glass substrate with fine surface roughness formed after the second etching alone, the graph represented by the alternate long and short dash line marked with “A” represents transmittance of a quartz glass substrate with fine surface roughness formed after the first etching carried out under conditions A and the second etching and the solid line marked with “B” represents transmittance of a quartz glass substrate with fine surface roughness formed after the first etching carried out under conditions B and the second etching.

Table 3 shows the conditions A of the first etching.

TABLE 3

| | Gas | | | | |
|---|---|---|---|---|---|
| | component | | RF (high- | | |
| Gas | and gas | | frequency) | | Etching |
| pressure | flow rate | Mode | power | Temperature | time |
| 1.0 Pa | Ar: 20 ml/min | Ion | 100 W | 2.0° C. | 900 sec |
| | | etching | | | |

The conditions B of the first etching are identical with those shown in Table 1. The conditions of the second etching for each of the graph represented by the broken line, the graph represented by the alternate long and short dash line and the graph represented by the solid line in FIG. 26 are identical with those shown in Table 2. Accordingly, the conditions of the first etching and the conditions of the second etching for the graph represented by the solid line in FIG. 26 are identical with those for the graph represented by the solid line in FIG. 7 and therefore the graph represented by the solid line in FIG. 26 is identical with the graph represented by the solid line in FIG. 7. According to Table 1 and Table 3, the etching time of the conditions B is twice as great as that of the conditions A and concerning the other conditions besides etching time, there is no difference between the conditions A and the conditions B.

When the first etching is carried out under the conditions A, an outermost layer of thickness of 10 nanometers of the substrate is removed and when the first etching is carried out under the conditions B, an outermost layer of thickness of 20 nanometers of the substrate is removed. A thickness of a removed layer is estimated using etching time and an etching rate. The etching rate was obtained as below. A certain area of a surface of another quartz glass substrate was made to undergo the first etching under the conditions shown in Table 1, for example, and a difference in height of the substrate between the area that was made to undergo the first etching and an area that was not made to undergo the first etching. A difference in height of the substrate was measured by an atomic force microscope (AFM). In this case the etching rate was approximately 0.011 nanometers per second. According to the finding of the inventors, when an outermost layer of thickness of 20 nanometers or more of the substrate is removed by the first etching and then the second etching is carried out, fine surface roughness can be preferably shaped and a desirable transmittance can be obtained. When a thickness of an outermost layer removed by the first etching is smaller than 20 nanometers, an average pitch of fine surface roughness cannot be adjusted appropriately and therefore a desirable transmittance cannot be obtained.

FIG. 27 shows transmittance of quartz glass substrates with and without fine surface roughness. The horizontal axis of FIG. 27 indicates wavelength, and the vertical axis of FIG. 27 indicates transmittance. The unit of the horizontal axis is nanometer, and the unit of the vertical axis is percent. Values of transmittance indicated by the vertical axis of FIG. 27 are measured values of normal-incidence transmissivity of a quartz glass substrate. Fine surface roughness is formed on each of both sides of the substrate under certain conditions. In FIG. 27, the long dash line marked with “unprocessed” represents transmittance of a quartz glass substrate without fine surface roughness, the short dash line marked with “C” represents transmittance of a quartz glass substrate with fine surface roughness formed after the first etching carried out under the conditions B and the second etching carried out under the conditions C, the solid line marked with “D” represents transmittance of a quartz glass substrate with fine surface roughness formed after the first etching carried out under the conditions B and the second etching carried out under the conditions D and the alternate long and short dash line marked with “E” represents transmittance of a quartz glass substrate with fine surface roughness formed after the first etching carried out under the conditions B and the second etching carried out under the conditions E. The conditions C, the conditions D and the conditions E will be described below.

The conditions D are identical with those shown in Table 2. Accordingly, the conditions of the first etching and the conditions of the second etching for the graph represented by the solid line in FIG. 27 are identical with those for the graph represented by the solid line in FIG. 7 and therefore the graph represented by the solid line in FIG. 27 is identical with the graph represented by the solid line in FIG. 7.

Table 4 shows the conditions C of the second etching.

TABLE 4

| | Gas | | | | |
|---|---|---|---|---|---|
| | component | | RF (high- | | |
| Gas | and gas | | frequency) | | Etching |
| pressure | flow rate | Mode | power | Temperature | time |
| 1.7 Pa | O2: 2 ml/min | Ion | 175 W | 2.0° C. | 1140 sec |
| | CHF3: 18 | etching | | | |
| | ml/min | | | | |

Table 5 shows the conditions E of the second etching.

TABLE 5

| | Gas | | | | |
|---|---|---|---|---|---|
| | component | | RF (high- | | |
| Gas | and gas | | frequency) | | Etching |
| pressure | flow rate | Mode | power | Temperature | time |
| 1.7 Pa | O2: 2 ml/min | Ion | 175 W | 2.0° C. | 2170 sec |
| | CHF3: | etching | | | |
| | 18 ml/min | | | | |

Table 6 shows an average pitch and an average depth of fine surface roughness formed after the first etching carried out under the conditions B and the second etching carried out under the conditions C, an average pitch and an average depth of fine surface roughness formed after the first etching carried out under the conditions B and the second etching carried out under the conditions D and an average pitch and an average depth of fine surface roughness formed after the first etching carried out under the conditions B and the second etching carried out under the conditions E.

TABLE 6

| | Average pitch (nm) | Average depth (nm) |
|---|---|---|
| Conditions C | 80 | 200 |
| Conditions D | 120 | 280 |
| Conditions E | 170 | 360 |

According to Tables 2 and 4 to 6, the average pitch and the average depth of fine surface roughness increase with etching time of the second etching. Accordingly, the shape of each graph shown in Table 27 can be adjusted through etching time of the second etching.

According to FIG. 27, transmittance of a quartz glass substrate with fine surface roughness formed on each of both sides of the substrate reaches a maximum at a wavelength around 350 nanometers in the case of C, reaches a maximum at a wavelength around 530 nanometers in the case of D and reaches a maximum at a wavelength around 780 nanometers in the case of E. In each case the maximum value of transmittance is greater than 99 percent. Accordingly, the minimum value of reflectance of each quartz glass substrate with fine surface roughness can be estimated to be smaller than 0.5 percent.

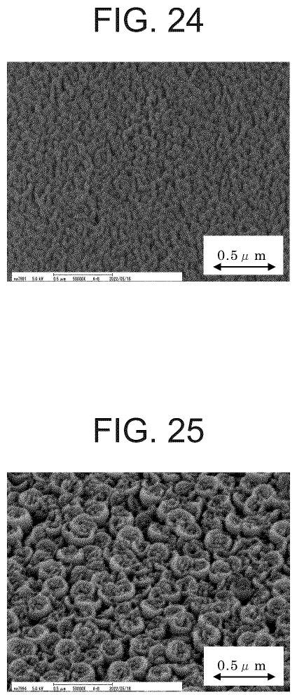

FIG. 24 shows a SEM (scanning electron microscope) image of a surface of the “with argon” substrate shown in FIG. 7.

FIG. 25 shows a SEM (scanning electron microscope) image of a surface of the “without argon” substrate shown in FIG. 7.

Comparing FIG. 24 and FIG. 25 with each other, a pitch of the fine surface roughness of the “with argon” substrate is smaller than that of the “without argon” substrate, and an aspect ratio of the fine surface roughness of the “with argon” substrate is greater than that of the “without argon” substrate. In a method without the first etching process, polymer particles that have been generated in the second etching process (the etching process with trifluoromethane (CHF₃) gas) attach to the glass substrate and function as an etching mask so that fine surface roughness is formed on the substrate. However, fine surface roughness with a smaller pitch and a higher aspect ratio cannot be formed without the first etching process (the etching process with argon gas), because the state of atoms on the substrate surface has not been changed by the first etching process before the second etching process as described above.

FIG. 4 is a flowchart for describing a method for manufacturing fine surface roughness on a quartz glass substrate according to another embodiment of the present invention.

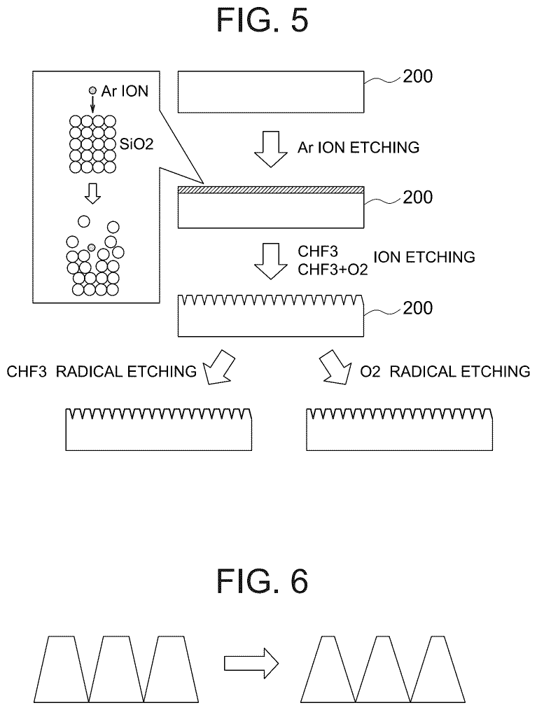

FIG. 5 is a drawing for illustrating the method for manufacturing fine surface roughness on a quartz glass substrate according to the embodiment of the present invention shown in FIG. 4.

In step S2010 of FIG. 4, the first etching process is carried out just as in the step S1010 of FIG. 2.

In step S2020 of FIG. 4, the second etching process is carried out just as in the step S1020 of FIG. 2.

In step S2030 of FIG. 4, the upper electrode 103 is connected to the high-frequency power source 107, and the lower electrode 105 is grounded. The etching apparatus 100 is supplied with trifluoromethane (CHF₃) gas or oxygen gas, and a high-frequency voltage is applied to the upper electrode 103 by the high-frequency power source 107. In the present step, trifluoromethane (CHF₃) cations or oxygen cations are attracted to the upper electrode 103 and do not contribute to a physical etching on the surface of the quartz glass substrate 200. In the present step, as shown in FIG. 5, a chemical etching process takes place through reactions between trifluoromethane (CHF₃) radicals or oxygen radicals and the surface of the quartz glass substrate 200. A radical is a molecule that carries no charge and has unpaired electrons. The etching process in the present step is milder and more isotropic compared with the second etching process. The etching process in the present step is referred to as a third etching process.

The third etching process changes the shape of fine surface roughness formed on the surface of the quartz glass substrate 200. How the shape is changed will be described below.

FIG. 6 illustrates how the third etching process changes the shape of fine surface roughness formed on the surface of the quartz glass substrate 200. Since the third etching process is more isotropic compared with the second etching process, the side of each projection of fine surface roughness is further made to undergo etching so that the shape of each projection is supposed to approach to a conical shape. In general, as the shape of each projection of fine surface roughness approaches to a conical shape, antireflective performance is improved. Accordingly, it is expected that the third etching process will improve antireflective performance.

Table 7 shows etching conditions of the first to third etching processes.

TABLE 7

| | Gas | | | | |
|---|---|---|---|---|---|
| | component | | RF (high- | | |
| Gas | and gas | | frequency) | | Etching |
| pressure | flow rate | Mode | power | Temperature | time |
| 1.0 Pa | Ar: 20 ml/min | Ion | 100 W | 2.0° C. | 1800 sec |
| | | etching | | | |
| 1.7 Pa | O2: 2 ml/min | Ion | 175 W | 2.0° C. | 1800 sec |
| | CHF3: 18 | etching | | | |
| | ml/min | | | | |
| 1.0 Pa | CHF3: 20 | Radical | 50 W | 2.0° C. | 300 sec |
| | ml/min | etching | | | |

The conditions of the first etching are identical with those shown in Table 1 and the conditions of the second etching are identical with those shown in Table 2.

Concerning the fine surface roughness formed on the quartz glass substrate, the average pitch (period) is 120 nanometers, and the average depth is 280 nanometers.

The values of the average pitch and average depth described above are identical with those of fine surface roughness after the second etching in the case of D. Values of an average pitch and an average depth of fine surface roughness remain unchanged during the third etching process.

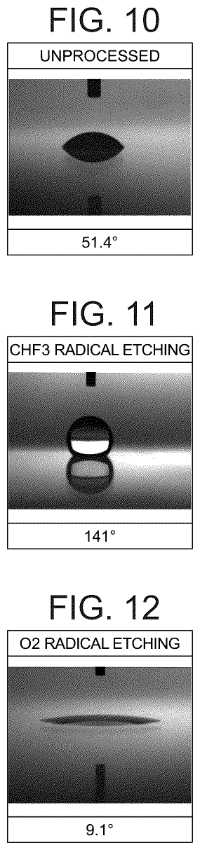

FIG. 10 is a photo of a waterdrop on a surface of a quartz glass substrate on which no fine surface roughness is formed.

FIG. 11 is a photo of a waterdrop on a surface of a quartz glass substrate with fine surface roughness which has undergone etching using trifluoromethane (CHF₃) gas in the third etching process.

FIG. 12 is a photo of a waterdrop on a surface of a quartz glass substrate with fine surface roughness which has undergone etching using oxygen gas in the third etching process.

The values of angle of contact of the waterdrops in FIGS. 10 to 12 are 51.4 degrees, 141 degrees and 9.1 degrees respectively. In general, angle of contact is defined as an angle between a free surface of quiescent liquid and a wall surface of a solid at a position where the free surface and the wall surface of the solid contact with each other, the angle being inside the liquid. A greater angle of contact means a greater water repellency and a smaller hydrophilicity.

According to FIGS. 10 to 12, etching using trifluoromethane (CHF₃) gas in the third etching process makes water repellency greater, and etching using oxygen gas in the third etching process makes hydrophilicity greater. Thus, water repellency or hydrophilicity of a surface can be changed through the third etching process.

It is supposed that in the third etching process using trifluoromethane (CHF₃) gas, chemical reactions alone take place on a surface of the fine surface roughness by radicals of trifluoromethane (CHF₃), and fluorine type hydrophobic groups grow there so that water repellency increases.

It is supposed that in the third etching process using oxygen gas, radicals of oxygen react with products generated by the second etching process on the surface of the fine surface roughness, and hydrophilic groups such as OH, CHO and COOH are generated on the surface so that hydrophilicity increases.

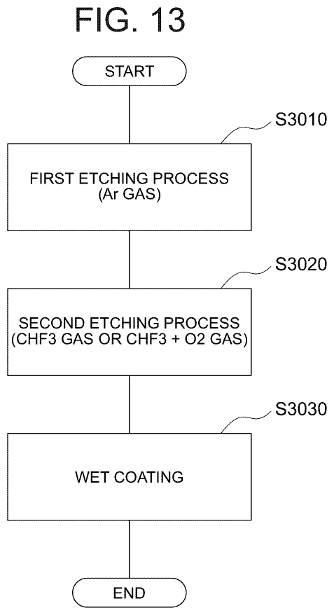

FIG. 13 is a flowchart for describing a method for manufacturing fine surface roughness on a quartz glass substrate according to still another embodiment of the present invention.

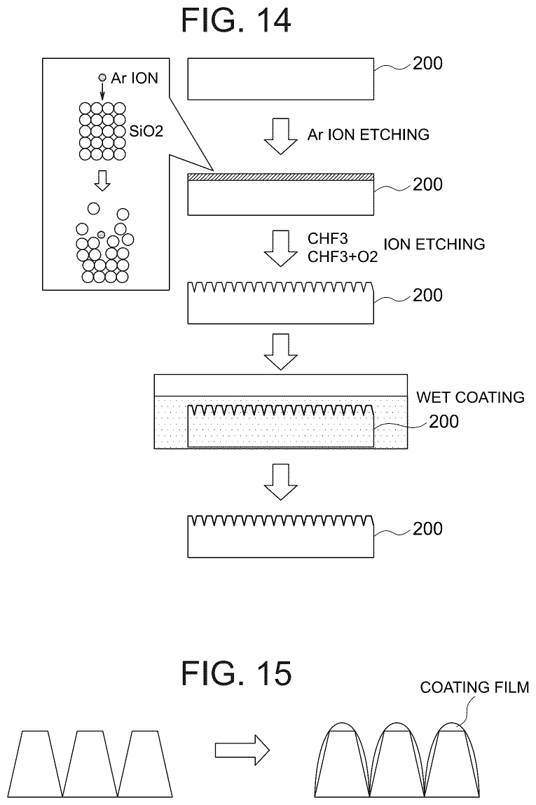

FIG. 14 is a drawing for illustrating the method for manufacturing fine surface roughness on a quartz glass substrate according to the embodiment of the present invention shown in FIG. 13

In step S3010 of FIG. 13, the first etching process is carried out just as in the step S1010 of FIG. 2.

In step S3020 of FIG. 13, the second etching process is carried out just as in the step S1020 of FIG. 2.

In step S3030 of FIG. 13, the quartz glass substrate 200 is taken out of the etching apparatus 100 and made to undergo a wet coating process by dipping the substrate into a liquid for water repellant coating (FG-5080F130-0.1 made by Fluoro Technology Co., LTD., for example) or a liquid for hydrophilic coating (SPRA-101 made by TOKYO OHKA KOGYO CO., LTD., for example) in a container as shown in FIG. 14. A wet coating process is a technique for forming a coating film through dipping into a liquid.

FIG. 15 illustrates how the shape of the fine surface roughness formed on the surface of the quartz glass substrate changes through the wet coating process. Through the wet coating process, a coating film is formed on the surface of the fine surface roughness. As shown in FIG. 15, the coating film changes the shape of projections of the fine surface roughness. By the way of example, the average pitch of the fine surface roughness is 120 nanometers as described above, and the thickness of the coating film is 10 to 20 nanometers. Further, since the value of refractive index of a coating liquid of which the coating film is made is between that of quartz and that of air, the coating film functions as a preferable intermediate layer between quartz and air from the viewpoint of antireflective performance.

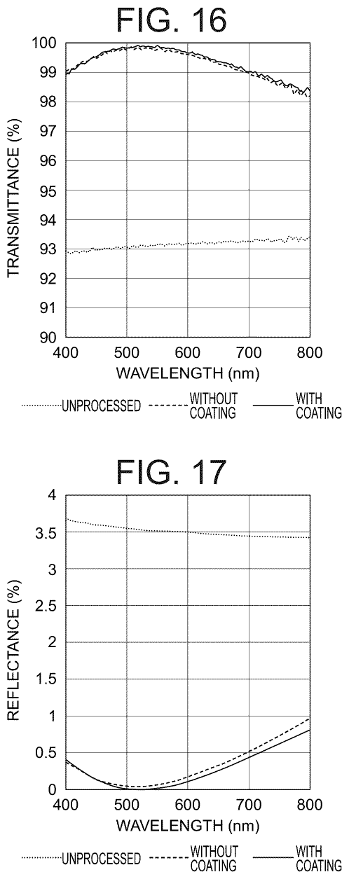

FIG. 16 shows transmittance of a quartz glass substrate provided with fine surface roughness that has been made to undergo a wet coating process. The wet coating liquid is the liquid for water repellant coating (FG-5080F130-0.1 made by Fluoro Technology Co., LTD.). The horizontal axis of FIG. 16 indicates wavelength, and the vertical axis of FIG. 16 indicates transmittance. The unit of the horizontal axis is nanometer, and the unit of the vertical axis is percent. In FIG. 16, the solid line marked with “with coating” represents transmittance of a quartz glass substrate provided with fine surface roughness that has been made to undergo the wet coating process, the broken line marked with “without coating” represents transmittance of a quartz glass substrate provided with fine surface roughness that has not been made to undergo the wet coating process, and the dotted line marked with “unprocessed” represents transmittance of a quartz glass substrate on which no fine surface roughness is formed. According to FIG. 16, transmittance of the substrate “with coating” is greater by 5 to 6.5 percent than transmittance of the “unprocessed” substrate across the whole range of wavelength. Further, transmittance of the substrate “with coating” is greater than transmittance of the substrate “without coating” in the wavelength range from 450 to 800 nanometers.

FIG. 17 shows reflectance of the quartz glass substrate provided with fine surface roughness that has been made to undergo the wet coating process. The horizontal axis of FIG. 17 indicates wavelength, and the vertical axis of FIG. 17 indicates reflectance. The unit of the horizontal axis is nanometer, and the unit of the vertical axis is percent. In FIG. 17, the solid line marked with “with coating” represents reflectance of the quartz glass substrate provided with fine surface roughness that has been made to undergo the wet coating process, the broken line marked with “without coating” represents reflectance of the quartz glass substrate provided with fine surface roughness that has not been made to undergo the wet coating process, and the dotted line marked with “unprocessed” represents reflectance of the quartz glass substrate on which no fine surface roughness is formed. According to FIG. 17, reflectance of the substrate “with coating” is smaller by 2.5 to 3.5 percent than reflectance of the “unprocessed” substrate across the whole range of wavelength. Further, reflectance of the substrate “with coating” is smaller than reflectance of the substrate “without coating” in the wavelength range from 450 to 800 nanometers.

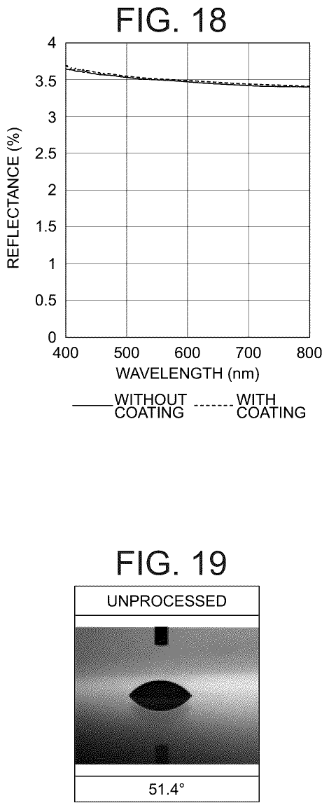

FIG. 18 shows reflectance of a quartz glass substrate on which no fine surface roughness is formed and which has been made to undergo the wet coating process. The horizontal axis of FIG. 18 indicates wavelength, and the vertical axis of FIG. 18 indicates reflectance. The unit of the horizontal axis is nanometer, and the unit of the vertical axis is percent. In FIG. 18, the broken line marked with “with coating” represents reflectance of a quartz glass substrate on which no fine surface roughness is formed and which has been made to undergo the wet coating process, and the solid line marked with “without coating” represents reflectance of a quartz glass substrate on which no fine surface roughness is formed and which has not been made to undergo the wet coating process.

According to FIG. 18, the wet coating process has no influence on reflectance of the quartz glass substrate on which no fine surface roughness is formed. Accordingly, it has been verified that reduction in reflectance thorough a wet coating process is unique to fine surface roughness.

FIG. 19 is a photo of a waterdrop on a surface of a quartz glass substrate on which no fine surface roughness is formed.

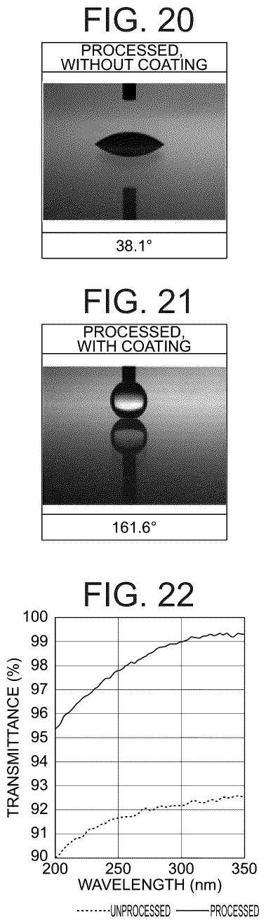

FIG. 20 is a photo of a waterdrop on a surface of a quartz glass substrate on which fine surface roughness is formed, the fine surface roughness having not been made to undergo wet coating.

FIG. 21 is a photo of a waterdrop on a surface of a quartz glass substrate on which fine surface roughness is formed, the fine surface roughness having been made to undergo wet coating.

According to FIGS. 19-21, water repellency of the surface of the quartz glass substrate on which fine surface roughness is formed is smaller than that of the surface of the quartz glass substrate on which no fine surface roughness is formed, and water repellency of the surface of the quartz glass substrate on which fine surface roughness is formed, the fine surface roughness having been made to undergo wet coating is remarkably greater than that of the surface of the quartz glass substrate on which no fine surface roughness is formed.

The manufacturing methods described above are used to form antireflective fine surface roughness for visible light. A manufacturing method used to form antireflective fine surface roughness for deep ultraviolet light will be described below.

The manufacturing method used to form antireflective fine surface roughness for deep ultraviolet light is identical with that shown in FIG. 2. However, etching conditions should be determined such that an average pitch and an average depth are reduced depending on a wavelength of deep ultraviolet light.

Table 8 shows etching conditions of the first and second etching processes carried out to form antireflective fine surface roughness for deep ultraviolet light.

TABLE 8

| | Gas | | | |
|---|---|---|---|---|
| | component | RF (high- | | |
| Gas | and gas | frequency) | | Etching |
| pressure | flow rate | power | Temperature | time |
| 1.0 Pa | Ar: 20 ml/min | 100 W | 2.0° C. | 1800 sec |
| 2.5 Pa | O2: 2 ml/min | 200 W | 2.0° C. | 700 sec |
| | CHF3: 18 ml/min | | | |

The etching time of the second etching process is smaller than that in the method for visible light shown in Table 2 so as to reduce an average pitch and an average depth of fine surface roughness. In the fine surface roughness for deep ultraviolet light, an average pitch is 65 nanometers, and an average depth is 200 nanometers.

FIG. 22 shows transmittance of a quartz glass substrate on which fine surface roughness is formed. The horizontal axis of FIG. 22 indicates wavelength, and the vertical axis of FIG. 22 indicates transmittance. The unit of the horizontal axis is nanometer, and the unit of the vertical axis is percent. In FIG. 22, the solid line marked with “processed” represents transmittance of the quartz glass substrate on which fine surface roughness is formed, and the broken line marked with “unprocessed” represents transmittance of a quartz glass substrate on which no fine surface roughness is formed. According to FIG. 22, a value of transmittance at a certain wavelength of the “processed” substrate is greater by 5 to 6.5 percent than a value of transmittance at the certain wavelength of the “unprocessed” substrate across the whole range of wavelength.

Values of transmittance indicated by the vertical axis of FIG. 22 are measured values of normal-incidence transmissivity of each quartz glass substrate. A value of transmittance in the whole range is greater than 95 percent. Accordingly, a value of reflectance in the whole range can be estimated to be smaller than 2.5 percent.

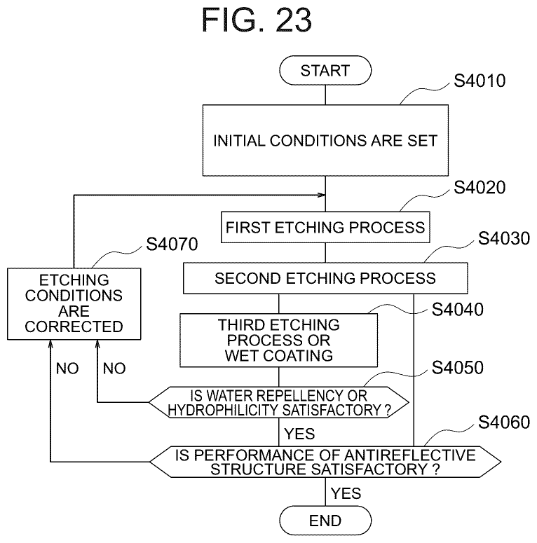

FIG. 23 is a flowchart for outlining the methods for manufacturing fine surface roughness on a quartz glass substrate according to the present invention.

In step of S4010 of FIG. 23, initial values of etching conditions are determined.

In step of S4020 of FIG. 23, the first etching process is carried out.

In step of S4030 of FIG. 23, the second etching process is carried out.

In step of S4040 of FIG. 23, the third etching process or a wet coating process is carried out. The first to third etching processes are carried out in an etching apparatus, and the wetting coating process is carried out by dipping the substrate in a wet coating liquid in a container.

In step of S4050 of FIG. 23, water repellency or hydrophilicity of the substrate with fine surface roughness is evaluated. If the result of evaluation is affirmative, the process goes to S4060. If the result of evaluation is negative, the process goes to S4070. The steps of S4040 and S4050 can be omitted.

In step of S4060 of FIG. 23, antireflective performance of the substrate with fine surface roughness is evaluated. If the result of evaluation is affirmative, the process is terminated. If the result of evaluation is negative, the process goes to S4070.

In step of S4070 of FIG. 23, the etching conditions are corrected, and the process goes back to step S4020.

A method for manufacturing fine surface roughness on a surface of a quartz glass substrate, according to an embodiment includes: making the quartz glass substrate undergo ion etching with argon gas alone such that through the ion etching with argon a layer of a thickness of 20 nanometers or greater is removed from a surface of the quartz glass substrate; and making the quartz glass substrate undergo reactive ion etching with trifluoromethane (CHF₃) gas or a mixed gas of trifluoromethane (CHF₃) and oxygen such that after the reactive ion etching surface roughness having an average pitch in a range from 30 nanometers to 200 nanometers is formed on the surface of the quartz glass substrate and there exists light having a wavelength in a range from 350 to 800 nanometers, for the light normal-incidence reflectivity of the surface being 1.5 percent or smaller or there exists light having a wavelength in a range from 200 to 350 nanometers, for the light normal-incidence reflectivity of the surface being 2.5 percent or smaller.

In the manufacturing method according to the present embodiment, the quartz glass substrate is made to undergo ion etching with argon gas alone such that through the ion etching with argon a layer of a thickness of 20 nanometers or greater is removed from a surface of the quartz glass substrate. According to the finding of the inventors, when an outermost layer of thickness of 20 nanometers or more of the substrate is removed by the first etching and then the second etching is carried out, fine surface roughness can be preferably shaped and a desirable transmittance can be obtained. The reason can be estimated as below. When an outermost layer of thickness of 20 nanometers or more of the substrate is removed by the first etching, the arrangement of atoms on the surface of the quartz glass substrate is changed in such a way that fine surface roughness can be easily formed on the surface of the quartz glass substrate by the second etching independently of an initial state of the surface and therefore fine surface roughness having a desired shape can be manufactured over a large area of the quartz glass substrate with stability through the second etching without preparing a mask prior to an etching process.

In the method for manufacturing fine surface roughness according to another embodiment, after the reactive ion etching there exists light having a wavelength in a range from 350 to 800 nanometers, for the light normal-incidence reflectivity of the surface being 0.5 percent or smaller.

In the method for manufacturing fine surface roughness according to another embodiment, after the reactive ion etching there exists light having a wavelength in a range from 350 to 800 nanometers, for the light normal-incidence transmissivity of the surface being 98.5 percent or greater or there exists light having a wavelength in a range from 200 to 350 nanometers, for the light normal-incidence reflectivity of the surface being 97.5 percent or greater.

In the method for manufacturing fine surface roughness according to another embodiment, a ratio of a flow rate of oxygen gas to a flow rate of the mixed gas is in a range from 0 to 50 percent.

According to the present embodiment, by supplying oxygen gas in the above-described range, polymer particles that have been generated by trifluoromethane (CHF₃) gas and have attached to the surface of the quartz glass substrate can be removed so that higher antireflective performance can be achieved.

The method for manufacturing fine surface roughness according to another embodiment further includes making the quartz glass substrate undergo radical etching with trifluoromethane (CHF₃) gas or oxygen gas in the ion etching apparatus in which the quartz glass substrate is placed on the first electrode, the first electrode is grounded and the second electrode is connected to the high frequency power source.

According to the present embodiment, still higher antireflective performance is achieved through radical etching. Further, water repellency is improved through radical etching with trifluoromethane (CHF₃) gas, and hydrophilicity is improved through radical etching with oxygen gas.

The method for manufacturing fine surface roughness according to another embodiment further includes making the quartz glass substrate undergo wet coating after making the quartz glass substrate undergo reactive ion etching.

According to the present embodiment, still higher antireflective performance is achieved through wet coating.

What is claimed is:

1. A method for manufacturing fine surface roughness on a surface of a quartz glass substrate, the method comprising:
making the quartz glass substrate undergo ion etching with argon gas alone such that through the ion etching with argon a layer of a thickness of 20 nanometers or greater is removed from a surface of the quartz glass substrate; and
making the quartz glass substrate undergo reactive ion etching with trifluoromethane (CHFs) gas or a mixed gas of trifluoromethane (CHFs) and oxygen such that after the reactive ion etching surface roughness having an average pitch in a range from 30 nanometers to 200 nanometers is formed on the surface of the quartz glass substrate and there exists light having a wavelength in a range from 350 to 800 nanometers, for the light normal-incidence reflectivity of the surface being 1.5 percent or smaller or there exists light having a wavelength in a range from 200 to 350 nanometers, for the light normal-incidence reflectivity of the surface being 2.5 percent or smaller.

2. The method for manufacturing fine surface roughness according to claim 1, wherein after the reactive ion etching there exists light having a wavelength in a range from 350 to 800 nanometers, for the light normal-incidence reflectivity of the surface being 0.5 percent or smaller.

3. The method for manufacturing fine surface roughness according to claim 1, wherein after the reactive ion etching there exists light having a wavelength in a range from 350 to 800 nanometers, for the light normal-incidence transmissivity of the surface being 98.5 percent or greater or there exists light having a wavelength in a range from 200 to 350 nanometers, for the light normal-incidence transmissivity of the surface being 97.5 percent or greater.

4. The method for manufacturing fine surface roughness according to claim 1, wherein a ratio of a flow rate of oxygen gas to a flow rate of the mixed gas is in a range from 0 to 50 percent.

5. The method for manufacturing fine surface roughness according to claim 1, further comprising making the quartz glass substrate undergo radical etching with trifluoromethane (CHF₃) gas or oxygen gas after the reactive ion etching.

6. The method for manufacturing fine surface roughness according to claim 1, further comprising making the quartz glass substrate undergo wet coating after the reactive ion etching.
